(19) United States
(12) Patent Application Publication
(10) Pub. No.: US 2026/0143885 A1
(43) Pub. Date: May 21, 2026

(54) AN INTEGRATED MICRO-LED DISPLAY DEVICE AND A DISPLAY PANEL

(71) Applicant: Xiamen University, Xiamen (CN)

(72) Inventors: Weijie GUO, Xiamen (CN); Canbin CHEN, Xiamen (CN); Yulin GAO, Xiamen (CN); Yijun LV, Xiamen (CN); Zhong CHEN, Xiamen (CN)

(21) Appl. No.: 18/705,804

(22) PCT Filed: Dec. 12, 2023
(86) PCT No.: PCT/CN2023/138093

§ 371 Date: Apr. 29, 2024

(30) Foreign Application Priority Data
Dec. 28, 2022 (CN) 202211692577.4

(51) Int. Cl. H10H 29/49; H10H 29/851

(52) U.S. Cl. CPC H10H 29/49; H10H 29/8514

(57) ABSTRACT

An integrated Micro-LED display device comprises a substrate and a plurality of display pixel units bonded on the substrate, each display pixel unit includes several Micro-LEDs and a driver IC, the first surface and the second surface of the substrate are respectively provided with a first metal circuit and a second metal circuit for connecting with the display pixel units, a part of the first metal circuit and a part of the second metal circuit are connected through several conducting vias set on the substrate, the first metal circuit and/or the second metal circuit comprise a positive bus and a negative bus, the driver IC and at least one of the bus are arranged on different surfaces of the substrate respectively, the driver ICs and the several Micro-LEDs are bonding to the circuit by means of mass transfer form display pixel arrays.

### CROSS REFERENCE OF RELATED APPLICATION

The application claims the priority of the Chinese patent application No. 2022116925774 filed on Dec. 28, 2022, the entire content of claim is incorporated in this application by reference.

### TECHNICAL FIELD

This application relates to the field of LED display technology, in particular to an integrated Micro-LED display device and a display panel composed of it.

### BACKGROUND

Micro-LED display is a very competitive next generation in display technology, full color display is a necessary performance of display products, liquid crystal display uses a color filter corresponding to each pixel to convert the white light emitted from the backlight into monochromatic light which comprises red, green and blue (RGB), to achieve full-color display, each pixel of the OLED display uses RGB light emitting material, so as to realize the self-luminous and full-color display, no matter which of full-color display technology is adopted, it is necessary to carry out a single addressable driver for the Micro-LEDs array.

Each chip in the array is electrically connected to the corresponding addressable driver unit on the driver substrate to ensure that the Micro-LEDs in each pixel unit can be driven independently, the main driver substrates of the existing technology includes Printed Circuit Board(PCB), and Thin Film Transistor(TFT) substrate, and Complementary Metal Oxide Semiconductor (CMOS) substrate, etc., CMOS substrate can achieve the highest resolution, but the substrate size is small and the cost is high, which can only be applied to small size micro LED display such as AR display, PCB substrate has the advantages of flexible design and double-sided routing, however, the existing PCB substrate is difficult to integrate addressing circuits and has a large pixel pitch, which is mainly applied in Micro-LED display with low resolution, the TFT substrate has its own addressing circuit unit, usually using 2T1C architecture driver circuit, which can make the Micro-LEDs of each pixel unit achieve independent addressing and active driving, the shortcomings are as follows:
(1) The TFT in 2T1C array has the problem of uneven I-V characteristics, in order to realize Vth compensation, it is usually necessary to use 4T2C or even 6T2C, and the driving becomes more complex, the Chinese patents whose application number are 202111102022.5, and 202111093965.6, and 202110534241.4, and 202110357172.4, etc., adopt that the discrete transistor integrated with the Micro-LEDs to form a display pixel array, and the discrete transistor can carry out Vth sorting, so as to avoid this problem;
(2) Only single-sided line can perform, wide line width and high resolution are contradictory, the cross section of the line is limited, the current supplied to the Micro-LEDs is limited, and the display brightness of the Micro-LED is limited.

### SUMMARY

In order to overcome the defects described above, this application proposes an integrated Micro-LED display device and a display panel, which can realize the high driving current of the Micro-LEDs, and realize the N-in-one integrated drive between the driver IC and the Micro-LEDs.

According to the first aspect of this application, an integrated Micro-LED display device is proposed, comprising a substrate and a plurality of display pixel units bonded on the substrate, each display pixel unit comprises several Micro-LEDs and a driver IC which are discrete mutually, the first surface of the substrate is provided with a first metal circuit for connecting with the display pixel units, the second surface of the substrate is provided with a second metal circuit for connecting with the display pixel units, a part of the first metal circuit and a part of the second metal circuit are connected through several conducting vias arranged on the substrate, the first metal circuit and/or the second metal circuit comprise a positive bus and a negative bus, the driver IC and the several Micro-LEDs are flip chips and form an electrical connection between the positive bus and the negative bus, and the driver IC and at least one of the bus are arranged on different surfaces of the substrate.

The display device described above can bond the discrete driver IC and the several Micro-LEDs to the circuit by means of mass transfer to form a display pixel array, and to realize the high driving current of the Micro-LEDs and N-in-one integrated drive between the driver IC and the Micro-LEDs.

Further, the first metal circuit includes a GND lead, a VCC lead and several first LED leads corresponding to the several Micro-LEDs, the GND lead is connected with the negative bus, and the VCC lead is connected with the positive bus.

Further, the driver IC is provided with a VCC pin, a GND pin and several LED pins corresponding to the several Micro-LEDs, the VCC pin is electrically connected with the VCC lead, and the GND pin is electrically connected with the GND lead.

Further, the several Micro-LEDs are provided with positive pins and negative pins, the several positive pins are electrically connected to the VCC lead, the several negative pins are electrically connected to the corresponding first LED leads, and the LED pins are electrically connected to the corresponding first LED leads respectively, so as to make the current flowing through the Micro-LEDs in the display pixel unit flow past the driver IC in the display pixel unit.

Further, the driver IC is arranged on the first surface of the substrate, and the positive bus and the negative bus are arranged on the second surface of the substrate.

Further, the several Micro-LEDs are arranged on the first surface of the substrate. At the same time, the power supply circuit and the device are set on both sides of the substrate surface separately, so that the power supply current circuit can have a wider wiring to pass a larger current, thereby increasing the power supply current.

Further, the several Micro-LEDs and driver IC are set respectively above the positive bus and the negative bus. The design is conducive to the heat dissipation of the device. Through the longitudinal heat transfer of the substrate, the heat generated by the chips can be transmitted to the metal circuit of the positive bus and the negative bus, and then the metal circuit can realize the external heat transfer by virtue of its high thermal conductivity.

Further, the several Micro-LEDs belonging to a same display pixel unit are arranged in a row and the arrangement orientation is parallel to one edge of the driver IC belonging to this display pixel unit. At this time, the driver IC blocks the transverse light propagation between two adjacent display pixel units in the same row, thereby reducing the transverse light crosstalk between the Micro-LEDs of the adjacent display pixel units.

Further, the negative bus is arranged on the first surface of the substrate, and the positive bus is arranged on the second surface of the substrate.

Further, the driver IC and the several Micro-LEDs belonging to the same display pixel unit are respectively arranged on different surfaces in the same area of the substrate.

Further, the driver IC and the positive bus for connecting with this driver IC are arranged on the same surface of the substrate and are stacked in a direction perpendicular to the substrate.

Further, the negative bus for connecting with the driver IC is arranged on another surface of the substrate and is stacked with the driver IC in a direction perpendicular to the substrate, by stacking the negative bus and the driver IC in the vertical space. The display pixel unit size can be reduced in the horizontal space.

Further, the extension direction of the negative bus and the positive bus is perpendicular to each other, thus, the Micro-LED and metal circuit can be vertically stacked on the upper and lower sides of the substrate, thereby reducing the area occupied by the wiring of the display pixel unit, and reducing the pixel size, and improving the pixel resolution, and enhancing the proportion of transparent display area to improve the luminousness.

Further, the driver IC and the several Micro-LEDs belonging to the same display pixel unit are stacked in a direction perpendicular to the substrate.

Further, the several Micro-LEDs are a combination of three primary colors Micro-LEDs which comprise blue Micro-LED and green Micro-LED and red Micro-LED, or a combination of a blue Micro-LED, a blue Micro-LED coated with red fluorescent material, and a blue Micro-LED coated with green fluorescent material.

Further, a part of or all of Micro-LEDs belonging to the same display pixel unit are fixed on a same supporting base to form a N-in-one Micro-LED, and are bonded to the substrate through the same supporting base, by bonding with multiple Micro-LEDs at one time, efficient manufacturing can be achieved.

Further, the N-in-one Micro-LED is provided with an island-shaped luminous structure, which is a cylinder or a hollow circular cylinder, the luminescence of different wavelengths is realized by the nanocolumn or nanoring structure with different diameters.

Further, a single display pixel unit has four Micro-LEDs.

Further, two of the four Micro-LEDs emit red light, while the others thereof emit blue light and green light respectively.

Further, the four Micro-LEDs emit red light, blue light, green light and white light respectively.

Further, the several Micro-LEDs are packaged as MiP (Micro-LED in Package) packages, during manufacturing, the photoelectric parameters of the MiP package can be measured and graded, so that the photoelectric parameters between the pixel units in the display screen can have a high consistency, so as to realize a high-quality display effect.

Further, an optical adhesive layer is provided above and/or below the MiP package, display pixel unit and/or substrate for seal protection, the optical adhesive layer provides a necessary protection for devices and circuits to avoid damage during manufacturing.

Further, the surface of the driver IC is covered with a light shielding layer for shading treatment.

Further, the substrate is transparent, thus, the non-wired area in the display device is transparent to achieve high-resolution transparent display.

Further, the first surface on which the Micro-LEDs are arranged is setting as the front side, a number of Micro-LEDs are symmetrically arranged on the back side to achieve a double-sided display.

Further, a same driver IC is employed to drive the Micro-LED on both sides, sharing the same driver IC can realize the simultaneous high-resolution display of the display screen on both sides.

Further, the multiple display pixel units are arranged in an array, and the driver ICs for the display pixel units arranged in a same row are connected in series from end to end to form an electrical connection.

In the second aspect, the present application provides a display panel comprising any of the integrated Micro-LED display device described in the first aspect.

This application presents an integrated Micro-LED display device and a display panel composed of the device. The Micro-LED display device integrates the discrete driver IC with the Micro-LEDs, which comprehensively complements the advantages of PCB substrate and TFT substrate. During manufacturing, several Micro-LEDs and a driver IC which are discrete mutually can be bonded to the circuit substrate board to form a pixel array by means of mass transfer, at the same time, it achieves discrete integration and high power supply current to achieve high-performance Micro-LED display effect.

### BRIEF DESCRIPTION OF THE DRAWINGS

The attached drawings illustrate embodiments and are used together with the description to explain the rationale of this application, the components are not necessarily proportional to each other, and the same pictorial markings refer to corresponding similar parts.

FIG. 1 is a structural diagram of the integrated Micro-LED display device in the first embodiment of this application;

FIG. 2 is a local diagram of the first surface of the integrated Micro-LED display device in the first embodiment of this application;

FIG. 3 is a schematic diagram of the circuit and welding pins of the integrated Micro-LED display device in the first embodiment of this application;

FIG. 4 is a local diagram of the second surface of the integrated Micro-LED display device in the first embodiment of this application;

FIG. 5 is a longitudinal profile diagram of the integrated Micro-LED display device in the first embodiment of this application;

FIG. 6 is a local diagram of the first surface of the integrated Micro-LED display device in the second embodiment of this application;

FIG. 7 is a longitudinal profile diagram of the integrated Micro-LED display device in the second embodiment of this application;

FIG. 8 is a structural diagram of the integrated Micro-LED display device in the third embodiment of this application;

FIG. 9 is a longitudinal profile diagram of the integrated Micro-LED display device in the third embodiment of this application;

FIG. 10 is a structural diagram of the integrated Micro-LED display device in the fifth embodiment of this application;

FIG. 11 is a structural diagram of the integrated Micro-LED display device in the sixth embodiment of this application;

FIG. 12 is a longitudinal profile diagram of the integrated Micro-LED display device in the sixth embodiment of this application.

FIG. 13 is a schematic diagram of the integrated Micro-LED display device in the seventh embodiment of this application;

FIG. 14 is a structural diagram of the N-in-one Micro-LED in the seventh embodiment of this application;

FIG. 15 is a structural diagram of the N-in-one Micro-LED in the eighth embodiment of this application;

FIG. 16 is a structural diagram of the N-in-one Micro-LED in the ninth embodiment of this application;

FIG. 17 is a schematic diagram of the integrated Micro-LED display device in the tenth embodiment of this application;

FIG. 18 is a schematic diagram of the integrated Micro-LED display device in the eleventh embodiment of this application.

FIG. 19 is a schematic diagram of the integrated Micro-LED display device in the twelfth embodiment of this application;

FIG. 20 is a longitudinal profile diagram of the integrated Micro-LED display device in the thirteenth embodiment of this application;

FIG. 21 is a longitudinal profile diagram of the integrated Micro-LED display device in the fourteenth embodiment of this application.

FIG. 22 is a longitudinal profile diagram of the integrated Micro-LED display device in the fifteenth embodiment of this application;

FIG. 23 is a longitudinal profile diagram of the integrated Micro-LED display device in the sixteenth embodiment of this application;

FIG. 24 is a longitudinal profile diagram of the integrated Micro-LED display device in the seventeenth embodiment of this application.

### DETAILED DESCRIPTION OF THE DISCLOSURE

Embodiments of the present application are described below to understand the present application better, other embodiments and many expected benefits of embodiments can be recognized through the detailed description below, it should be noted that in this application, relational terms such as first and second are used only to distinguish one entity or operation from the another, and do not necessarily require or imply any such actual relationship or order between these entities or operations, furthermore, the term “includes”, “contains” or any other variation is intended to cover non-exclusive inclusion, so that a process, method, article or equipment comprising a set of elements includes not only those elements but also other elements not expressly listed, or elements inherent to such process, method, article or equipment, in the absence of further restrictions, composed by the statement “including . . . ” a defined element does not preclude the existence of additional identical elements in a process, method, article or device existing in the element.

### Embodiment 1

FIG. 1 is a structural diagram of the Micro-LED display device in this embodiment, the display pixel unit of the integrated Micro-LED display device comprises a driver IC 1 and three Micro-LEDs which are discrete mutually. The Micro-LEDs contains a first Micro-LED 2, a second Micro-LED 3 and a third Micro-LED 4. The driver IC 1 drives the first Micro-LED 2, the second Micro-LED 3 and the third Micro-LED 4. In this embodiment, the driver IC 1 and three Micro-LEDs are arranged on the upper surface of a substrate 5. The driver IC 1 and the three Micro-LEDs are flip chips, whose welding pins are located on their own lower surface, so that they can use reflow soldering or eutectic bonding with the pad on the surface of the substrate 5.

Substrate 5 is not only used for the welding of the chip, but also participates in the interconnection between the chips, the two surfaces of substrate 5 are respectively provided with a first metal circuit and a second metal circuit. The first metal circuit is arranged on the upper surface of the substrate 5, including a first input lead 61, a first output lead 62, a first GND lead 63, three first LED leads 64 and the VCC lead 65. The second metal circuit is arranged on the lower surface of the substrate 5, including a negative bus 71 and a positive bus 72. The negative bus 71 and the positive bus 72 are connected to the first metal circuit through a first conducting via 81 and a second conducting via 82 respectively, to form a power supply current loop. The three first LED leads 64 are corresponding to the first Micro-LED 2, the second Micro-LED 3, and the third Micro-LED 4 respectively. All first GND leads 63 get through the substrate 5 to connect with the negative bus 71 electrically by the first conducting via 81. And all VCC leads 65 get through the substrate 5 to connect with the positive bus 72 electrically by the second conducting vias 82.

In this embodiment, the positive bus 72 and the negative bus 71 are arranged on the lower surface of the substrate 5. The driver IC 1 and the three Micro-LEDs are arranged on the upper surface of the substrate 5. The design is to realize the spatial separation between the power supply circuit and the device, the current circuit can have a wide wiring, and the current supply can be increased.

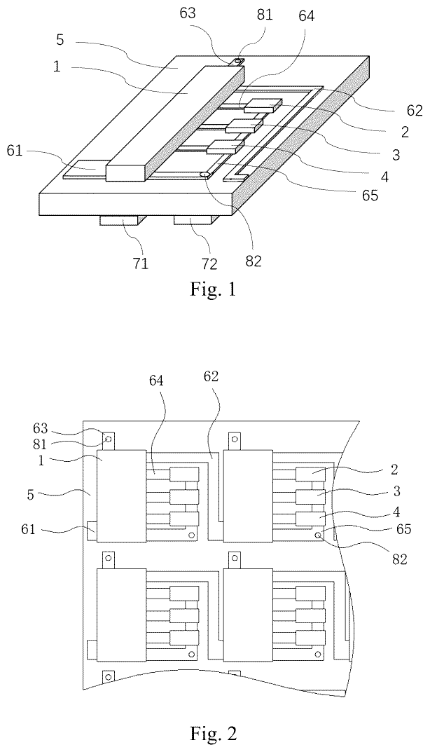

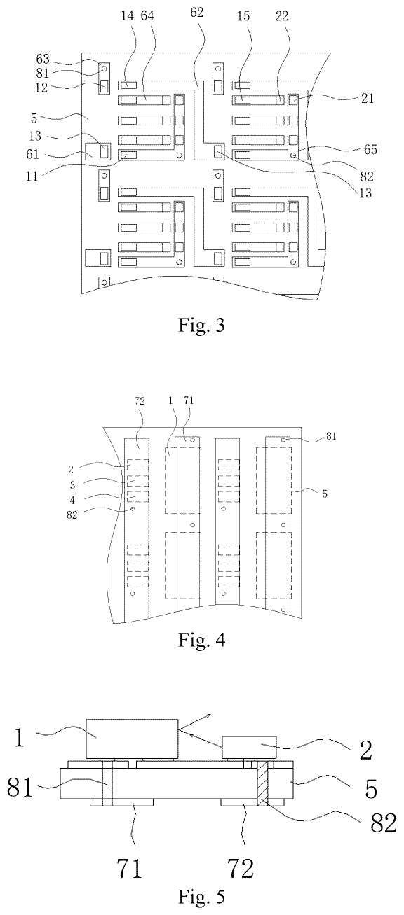

FIG. 2 is a local diagram of the first surface of the Micro-LED display device in this embodiment. FIG. 3 is a schematic diagram of the wiring and welding pins of the Micro-LED display device in this embodiment. FIG. 4 is a local diagram of the second surface of the Micro-LED display device in this embodiment. A driver IC 1 is provided with a VCC pin 11, a GND pin 12, a input pin 13, an output pin 14, three LED pins 15. The VCC pin 11 is welded to the VCC lead 65 and the GND pin 12 is welded to the first GND lead 63, in a display pixel array, all display pixel units in the same column share a same negative bus 71 and a same positive bus 72.

The Micro-LED is provided with three positive pins 21 and three negative pins 22. The positive pins 21 of the Micro-LED are welded to the VCC lead 65. And the negative pins 22 of the Micro-LED are welded to their corresponding first LED leads 64. The three LED pins 15 of the driver IC 1 are welded to the corresponding first LED leads 64. Thus, in each display pixel unit, the current flowing through all Micro-LEDs in the display pixel unit passes through the driver IC 1 in the display pixel unit.

Multiple display pixel unit arrays are arranged as display pixel arrays. In the display pixel array, the driver ICs 1 in all display pixel units in the same row are connected in series through the first output leads 62. One end of the first output lead 62 is welded to the output pin 14 of driver IC 1 in the previous display pixel unit in the same row, and the other end of the first output lead 62 is welded to the input pin 13 of the driver IC 1 in the next display pixel unit in the same row. The driver IC 1 located in the first display pixel unit in each row. Its input pin 13 is welded to the first input lead 61, and its output pin 14 is welded to one end of the first output lead 62. The other end of the first output lead 62 is welded to the input pin 13 of the driver IC 1 in the next display pixel unit in the same row.

In each display pixel unit, the first Micro-LED 2, the Micro-LED 3, and Micro-LED 4 are rectangular. And the long sides of the three Micro-LEDs are parallel to each other. The Micro-LEDs are arranged in a direction parallel to one side of the driver IC 1.

FIG. 5 is a longitudinal profile diagram of the Micro-LED display device in the present embodiment, wherein the arrows indicate the direction of transverse light propagation, in this embodiment, the arrangement of the driver ICs and the Micro-LEDs makes the transverse light propagation between two adjacent display pixel units in the same row of the display pixel array blocked by the driver ICs 1, thereby eliminating the transverse light crosstalk between the Micro-LEDs of adjacent display pixel units. It can also be seen from FIG. 5 that the driver ICs 1 and the Micro-LEDs are directly above the positive bus 72 and the negative bus 71 respectively. They can conduct the heat generated by them to the metal circuits of the positive bus 72 and negative bus 71 through the longitudinal heat transfer of the substrate 5, and then realize the outward heat transfer with the help of the high thermal conductivity of the metal circuits.

In this embodiment, the light-emitting structure of the Micro-LEDs are as follows: the first Micro-LED 2 and the second Micro-LED 3 are provided with a first semiconductor layer, a multi-quantum well light-emitting layer and a second semiconductor layer. The multi-quantum well light-emitting layer is arranged between the first semiconductor layer and the second semiconductor layer. The first semiconductor layer contains a layer of N-type GaN and a buffer layer. The multi-quantum well light-emitting layer is formed by alternating stacking of two semiconductor layers with different components and thickness at the nanoscale, whose chemical formula is AlₓIn_{y}Ga_{z}N (x+y+z=1,0≤x≤1,0 ≤y≤1,0≤z≤1). The second semiconductor layer contains a P-type GaN layer and an electron blocking layer. The second Micro-LED 3 emits light in the blue band, and the typical peak wavelength of the luminescence spectrum is 467 nm. The first Micro-LED 2 emits light in the green band, and the typical peak wavelength of the luminescence spectrum is 532 nm. The third Micro-LED 4 is provided with a first semiconductor layer, a multi-quantum well light-emitting layer and a second semiconductor layer. The multi-quantum well light-emitting layer is arranged between the first semiconductor layer and the second semiconductor layer. The first semiconductor layer contains at least one layer of P-type AlGaAs. The multi-quantum well light-emitting layer of the third Micro-LED 4 is formed by alternating stacking of two semiconductor layers with different components and thickness at the nanoscale, whose chemical formula is AlₓGa_{y}In_{z}P (x+y+z=1, 0≤x≤1,0≤y≤1,0≤z≤1). The second semiconductor layer of the third Micro-LED 4 contains at least one layer of N-type AlGaAs. The third Micro-LED 4 emits light in the red band, and the typical peak wavelength of the luminescence spectrum is 625 nm.

This application does not restrict the arrangement order of multiple Micro-LEDs with different light-emitting assembly. In this embodiment, as shown in FIG. 1, the second Micro-LED 3 is located between the first Micro-LED 2 and the third Micro-LED 4. According to the requirements of Micro-LED arrangement in the display pixel unit, the first Micro-LED 2 can be set between the second Micro-LED 3 and the third Micro-LED 4, or the third Micro-LED 4 can be set between the first Micro-LED 2 and the second Micro-LED 3, etc.

### Embodiment 2

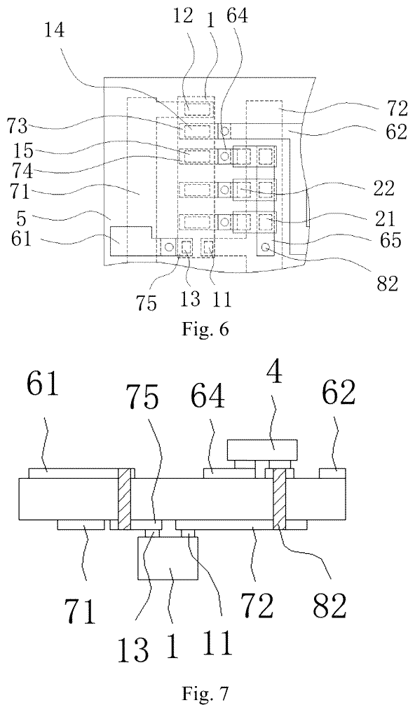

FIG. 6 is a local diagram of the first surface of the Micro-LED display device in the present embodiment, and FIG. 7 is a longitudinal profile diagram of the Micro-LED display device in the present embodiment. In this embodiment, a GND pin 12 of a driver IC 1 is welded to a negative bus 71. A second metal circuit also includes a second output lead 73, three second LED leads 74, and a second input lead 75. The second output lead 73 is connected to a first output lead 62 through a conducting via. The three LED pins 15 of the driver IC 1 are welded to the corresponding second LED leads 74 respectively. The second LED leads 74 are connected to a first LED lead 64 through conducting vias respectively. An output pin 14 of the driver IC 1 is welded to the second output lead 73. The second output lead 73 is connected to one end of a first output lead 62 through a conducting via, and the other end of the first output lead 62 is employed as a first input lead 61 of the subsequent display pixel unit in the same row. The first input lead 61 is connected to the second input lead 75 through a conducting via, and an input pin 13 of the driver IC 1 is welded to the second input lead 75.

The main difference from the display device in Embodiment 1 is that in this embodiment, the driver IC 1 is arranged on the lower surface of the substrate 5. The three Micro-LEDs, namely the first Micro-LED 2, and the second Micro-LED 3, and the third Micro-LED 4, are arranged on the upper surface of the substrate 5. The transverse space between the driver IC 1 and the three Micro-LEDs in each display pixel unit is reduced by this arrangement. Through vertical space separation, the transverse space is reduced, and the horizontal size of the display pixel unit is reduced.

### Embodiment 3

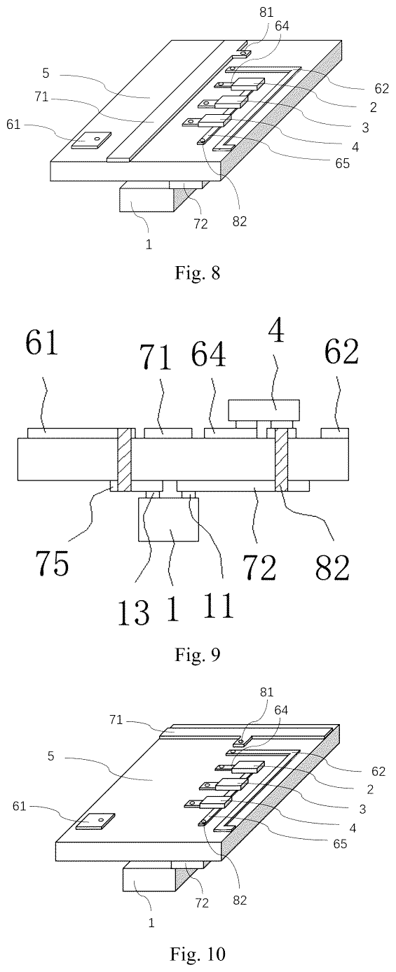

FIG. 8 is a structural diagram of the display device in the present embodiment, and FIG. 9 is a longitudinal profile diagram of the display device in the present embodiment, in this embodiment, a first metal circuit arranged on the upper surface of a substrate 5 also includes a negative bus 71, a positive bus 72 is still arranged on the lower surface of the substrate 5.

In the display pixel array, all VCC leads 65 pass through conducting vias 82 through the substrate 5 to connect to the positive bus 72.

A driver IC 1 is provided with a VCC pin 11, a GND pin 12, an input pin 13, an output pin 14, and three LED pins 15. The VCC pin 11 is welded to the positive bus 72. In a display pixel array, all display pixel units in the same column share this same negative bus 71 and this same positive bus 72.

The Micro-LED is provided with a positive pin 21 and a negative pin 22. The positive pin 21 of the Micro-LED is welded to the VCC lead 65, and the negative pin 22 of the Micro-LED is welded to its corresponding LED lead 64. The second surface metal circuit is provided with a second output lead, three second LED leads, a second input lead 75, and a second GND lead. The second LED leads 74 are corresponding to the first Micro-LED 2, the second Micro-LED 3, and the third Micro-LED 4. The second output lead 73 is connected to the first output lead 62 through a conducting via. The three LED pins 15 of the driver IC 1 are welded to the corresponding second LED leads 74, and the LED leads 74 set on the lower surface are connected to the LED lead 64 through a conducting via. The second GND lead is connected to the negative bus 71 through a metal conducting via 81. The GND pin of driver IC 1 is welded to the second GND lead.

In the display pixel array, the driver ICs 1 of all display pixel units in the same row are connected in series through the output lead 62. The output pin 14 of driver IC 1 is welded to the second output lead 73. The second output lead 73 is connected to one end of the first output lead 62 through a conducting via, and the other end of the first output lead 62 is employed as the first input lead 61 of the subsequent display pixel unit in the same row. The first input lead 61 is connected to the second input lead 75 through a conducting via, and the input pin 13 of the driver IC 1 is welded to the second input lead 75.

The rest of the wiring is the same as the display device shown in Embodiment 2.

In this embodiment, the negative bus 71 is vertically above the driver IC 1 in a direction perpendicular to the substrate, and the two are stacked to reduce the horizontal size of the display pixel unit.

### Embodiment 4

The main difference of the display device embodiment 1 in this embodiment is the light-emitting structure of the Micro-LED, this embodiment uses blue Micro-LED arrays combined with red light fluorescence and green light fluorescence conversion to realize full color display. A first Micro-LED, and a second Micro-LED, and a third Micro-LED are set the same. The first Micro-LED, and the second Micro-LED, and the third Micro-LED are provided with a first semiconductor layer, a multi-quantum well light-emitting layer, and a second semiconductor layer. The multi-quantum well light-emitting layer is arranged between the first semiconductor layer and the second semiconductor layer. The first semiconductor layer contains a layer of N-type GaN and a buffer layer. The multi-quantum well light-emitting layer is formed by alternating stacking of two semiconductor layers with different components and nanoscale thickness, whose chemical formula is AlₓIn_{y}Ga_{z}N (x+y+z=1,0≤x≤1,0≤y ≤1,0≤z≤1). The second semiconductor layer contains a layer of P-type GaN and an electron barrier layer. The luminescence spectrums of the three Micro-LEDs are in blue band, and the typical peak wavelength of the luminescence spectrum is 467 nm.

The Micro-LEDs can use red and green fluorescent materials to change the blue light, the red and green fluorescent materials are not limited to quantum dots, luminescent nanocrystalline materials, rare earth ion doped phosphors, manganese ion doped phosphors, details are as follows:
A first fluorescent conversion layer is also arranged above the first Micro-LED. The first fluorescent conversion layer can emit green light with the excitation of blue light, thus it converts the light emitted from the top of the first Micro-LED to green light. The first fluorescent conversion layer contains first luminescent particles such as quantum dots or rare earth ion doped phosphors. The quantum dots are selected from one or more of InP quantum dots, CdSe quantum dots, CdSe/ZnS quantum dots with core-shell structure, and CsPbX₃(X=Cl, Br, I) quantum dots with perovskite structure. The phosphors include one or more of Eu²⁺ doped β-Sialon, and Eu²⁺ doped Li₂CaSiO₄.

A second fluorescent conversion layer is also arranged above the third Micro-LED. The second fluorescent conversion layer can emit red light with the excitation of blue light, thus it converts the light emitted from the upper part of the third Micro-LED to red light. The second fluorescence conversion layer contains second luminescent particles, and the composition of the second luminescent particles include quantum dots, rare earth ion doped luminescent materials or fluoride phosphors. The quantum dots are selected from any one of InP quantum dots, CdSe quantum dots, CdSe/ZnS quantum dots with core-shell structure, and CsPbX₃(X=Cl, P, I) quantum dots with perovskite structure. Rare earth ion doped luminescent materials include any one of rare earth ion Eu²⁺ doped CaAlSiN₃, Eu²⁺ doped Ca_{0.8}Li_{0.2}Al_{0.8}Si_{1.2}N₃, Eu²⁺ doped (Ca, Sr, Ba)₂Si₅N₈, Eu²⁺, and Pr³⁺ doped YAG. Fluoride phosphors include any one of Mn⁴⁺ doped K₂SiF₆ phosphor, Mn⁴⁺ doped K₂GeF₆ phosphor, and Mn⁴⁺ doped K₂TiF₆ phosphor.

### Embodiment 5

FIG. 10 is a schematic diagram of the display device in this embodiment. The main difference from the display device in Embodiment 3 is that in this embodiment, a negative bus 71 is perpendicular to a positive bus 72 in space, thus the horizontal spacing between the Micro-LED and the positive bus 72 can be reduced. The wiring of the pixel unit can reduce the occupied area, which can improve the pixel resolution by reducing the pixel size and improve the transmittance by increasing the proportion of the transparent display area.

### Embodiment 6

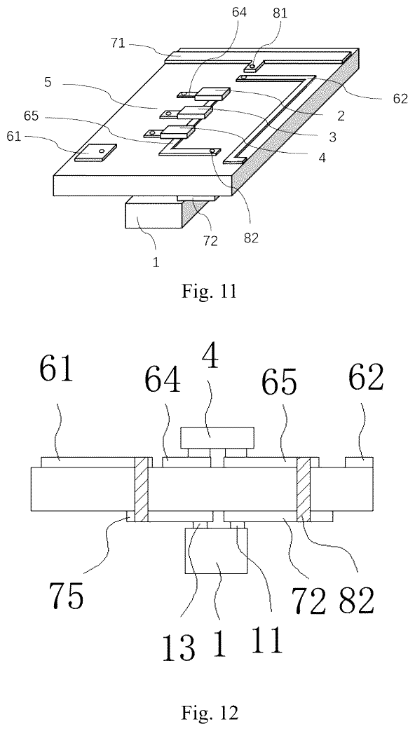

FIG. 11 is a structural diagram of the display device in the present embodiment, and FIG. 12 is a longitudinal profile diagram of the display device in the present embodiment. Different from Embodiment 3, in this embodiment, a driver IC 1 is arranged vertically below a first Micro-LED 2, a second Micro-LED 3, and a third Micro-LED 4. The horizontal size of the display pixel unit is reduced through the vertical stacking of the driver IC 1 and the Micro-LEDs. Thus, it can maximize the resolution of the display and achieve ultra-high resolution display.

### Embodiment 7

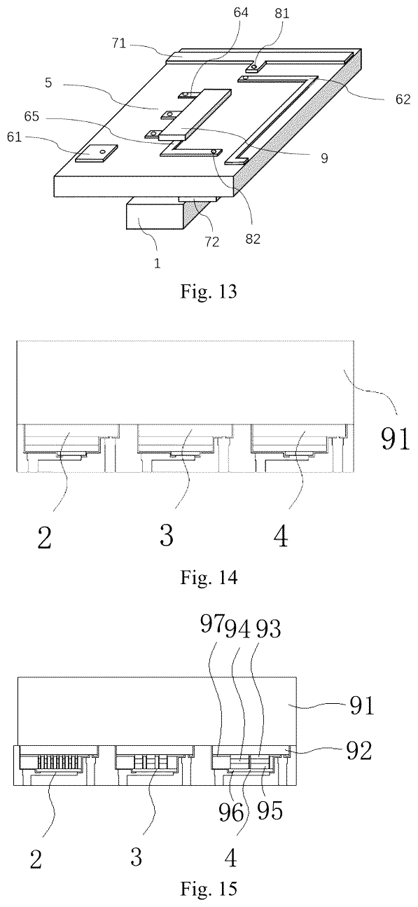

FIG. 13 shows a structural diagram of the display device in this embodiment, and FIG. 14 shows a structural diagram of the N-in-one Micro-LED 9 in this embodiment. In this embodiment, a first Micro-LED 2, a second Micro-LED 3, and a third Micro-LED 4 are arranged on a same supporting base 91 to form the N-in-one Micro-LED 9. The first Micro-LED 2, and the second Micro-LED 3, and the third Micro-LED 4 are arranged along the long side direction of the N-in-one Micro-LED 9 in sequence.

By using the N-in-one Micro-LED, the first Micro-LED 2, and the second Micro-LED 3, and the third Micro-LED 4 can be bonded together in one bonding to achieve high-efficiency manufacturing.

### Embodiment 8

FIG. 15 shows a structural diagram of the N-in-one Micro-LED in this embodiment, the main difference from Example 7 is that in this present example, each Micro-LED is provided with a first semiconductor layer 92 and several island-shaped luminous structures(for illustration, in FIG. 15, only the third Micro-LED 4 is marked with the accompanying FIG. 92-97). The width of a single island-shaped luminous structure is smaller than the width of the first semiconductor layer 92. The island-shaped luminous structure is provided with a third semiconductor layer 93, and a multi-quantum well luminescence layer 94, and a second semiconductor layer 95, and a current spreading layer 96. The multi-quantum well luminescence layer 94 is arranged between the third semiconductor layer 93 and the second semiconductor layer 95. The third semiconductor layer 93 has the same composition as the first semiconductor layer 92. The top surface of the third semiconductor layer 93 is connected to the lower surface of the first semiconductor layer 92. The side wall of a single island-shaped luminous structure is provided with an insulating layer, and the layers between the island-shaped luminous structures are filled to flatten.

The island-shaped luminous structure is a cylinder with a diameter between 150 nm and 2 microns. Except island-shaped luminous structures, the other area on the lower surface of the first semiconductor layer 92 is covered with a mask layer 97, which is made of titanium, or silicon dioxide, or silicon nitride.

The diameter of the island-shaped light-emitting structure of the second Micro-LED 3 is between 1 micron and 2 microns. The light emitted by the multi-quantum well light-emitting layer 94 passes through the first semiconductor layer 92, then emerges from the upper surface of the supporting base 91, and becomes green light finally.

When the diameter of the island-shaped light-emitting structure of the first Micro-LED 2 is between 500 nanometers and 1 micron, the light emitted by the multi-quantum well light-emitting layer 94, passes through the first semiconductor layer 92, and emerges from the upper surface of the supporting base 91, and becomes green light finally.

When the diameter of the island-shaped light-emitting structure of the third Micro-LED 4 is between 150 nanometers and 200 nanometers, the light emitted by the multi-quantum well light-emitting layer 94 passes through the first semiconductor layer 92, then emerges from the upper surface of the supporting base 91, and becomes red light finally.

### Embodiment 9

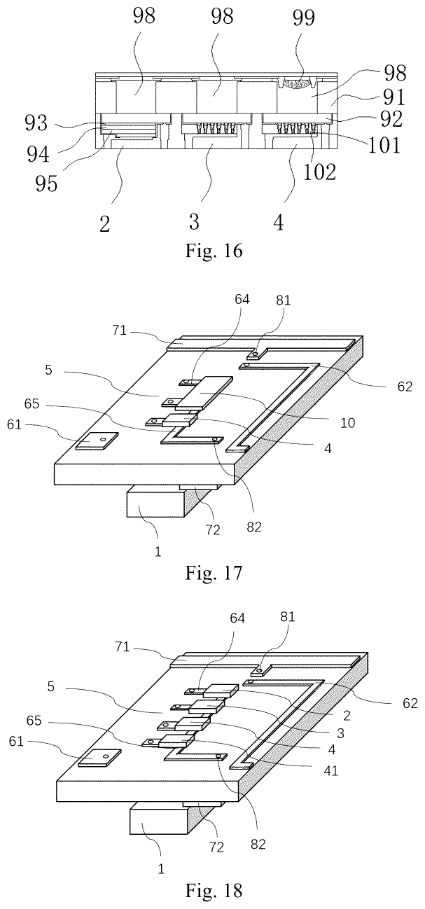

FIG. 16 shows the schematic assembly of an N-in-one Micro-LED in this embodiment. In this example, the Micro-LED is provided with a first semiconductor layer 92, and a third semiconductor layer 93, and a multi-quantum well luminescence layer 94, and a second semiconductor layer 95. The multi-quantum well luminescence layer 94 is arranged between the third semiconductor layer 93 and the second semiconductor layer 95. And the third semiconductor layer 93 has the same composition as that of the first semiconductor layer 92. The top surface of the third semiconductor layer 93 is connected to the lower surface of the first semiconductor layer 92. The difference from Example 7 is mainly that the etching of epitaxial layer of the second Micro-LED 3 and the third Micro-LED 4 forms an island-shaped luminous structure. In this embodiment, the island-shaped luminous structure is a hollow circular cylinder with an annular wall 101 and an inner cavity 102 (for illustration. in FIG. 16, only the third Micro-LED 4 is marked with the accompanying FIGS. 101 and 102), the wall thickness of the hollow circular cylinder island-shaped luminous structure is between 100 nm and 200 nm. The epitaxial layer of the first Micro-LED 2 is a planar structure, and the light emitted by its multi-quantum well luminescence layer 94 is green light. The light emitted from the multi-quantum-well luminescence layers 94 of the second Micro-LED 3 and the third Micro-LED 4 is blue due to stress relaxation.

Through holes 98 are arranged on the supporting base 91 and correspond to the three Micro-LEDs in the longitudinal direction. A red light fluorescence conversion layer 99 is arranged in the through hole 98 corresponding to the third Micro-LED 4, the red fluorescence conversion layer 99 can emit red light with the excitation of blue light, thus converting blue light emitting to red light, which emits from the multi-quantum well luminescence layer 94 of the third Micro-LED 4 and pass through the through-hole 98. The red fluorescence conversion layer 99 contains red light emitting particles, which contain quantum dots, or rare earth ion doped luminescent materials, or fluoride phosphors. The quantum dots are selected from any one of the InP quantum dots, CdSe quantum dots, CdSe/ZnS quantum dots with core-shell structure, and CsPbX₃(X=Cl, Br, I)quantum dots with perovskite structure. Rare earth ion doped luminescent materials include one of rare earth ion Eu²⁺ doped CaAlSiN₃, Eu²⁺ doped Ca_{0.8}Li_{0.2}Al_{0.8}Si_{1.2}N3, Eu²⁺ doped (Ca, Sr, Ba)₂Si₅N₈, Eu²⁺, and Pr³⁺ doped YAG. Fluoride phosphors include any one of Mn⁴⁺ doped K₂SiF₆ phosphor, Mn⁴⁺ doped K₂GeF₆ phosphor, and Mn⁴⁺ doped K₂TiF₆ phosphor.

### Embodiment 10

FIG. 17 shows a structural diagram of the display device in the present embodiment, the difference from Example 3 is that this display device in the present embodiment is arranged with a driver IC 1 and two Micro-LEDs. The two Micro-LEDs are a two-in-one Micro-LED 10 and a third Micro-LED 4, the arrangement makes the material system of the display device simpler.

Specifically, the light-emitting structure of the two-in-one Micro-LED 10 is similar to that of the three-in-one Micro-LED in embodiment 9, which is a hollow circular cylinder island-shaped light-emitting structure, the two Micro-LEDs emit blue light and green light respectively while the third Micro-LED 4 emits red light.

### Embodiment 11

FIG. 18 shows a schematic of the structure of the display device in this embodiment. The main difference from Example 3 is that each display pixel unit of the display device in this example includes four Micro-LEDs, namely, a first Micro-LED 2, and a second Micro-LED 3, and a third Micro-LED 4, and a fourth Micro-LED 41. The luminous bands of the first Micro-LED 2 and the fourth Micro-LED 41 are both red light band, in another embodiment, the fourth Micro-LED 41 can also emit white light.

### Embodiment 12

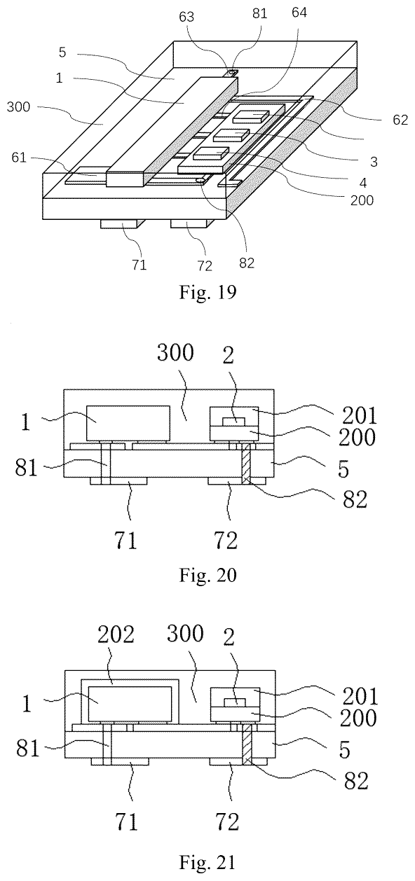

FIG. 19 shows a schematic of the structure of the display device in this embodiment, the difference from the display device in Example 1 is that a first Micro-LED 2, and a second Micro-LED 3, and a third Micro-LED 4 are packaged on a packaging substrate of MiP (Micro-LED in Package) to form a MiP package 200. Then, the MiP package 200 is welded to the upper surface of the substrate 5 to realize an electrical connection between the substrate 5 and the Micro-LEDs. Subsequently, a first optical adhesive layer 300 is covered above the whole display pixel unit to realize the protection of all devices and circuits.

By packaging the Micro-LEDs into the MiP package 200, the photoelectric parameters of the MiP package 200 can be measured and graded during production, so as to achieve a high consistency of the photoelectric parameters between the pixel units in the display, and to realize a high quality display effect.

### Embodiment 13

FIG. 20 shows a schematic of the structure of the display device in this embodiment. The difference from Example 12 is mainly that this packaging substrate of the display device in this embodiment is covered with a third optical adhesive layer 201, which is used to seal and protect the MiP package 200, so as to avoid the Micro-LED inside the MiP package 200 from being scratched.

### Embodiment 14

FIG. 21 shows a longitudinal profile of the display device in this embodiment. The main difference from Example 13 is that the top and side surfaces of the driver IC 1 of the display device in the present embodiment are also covered with a light shielding layer 202, which is used to shade the driver IC 1, the light shielding layer 202 can be white or black.

### Embodiment 15

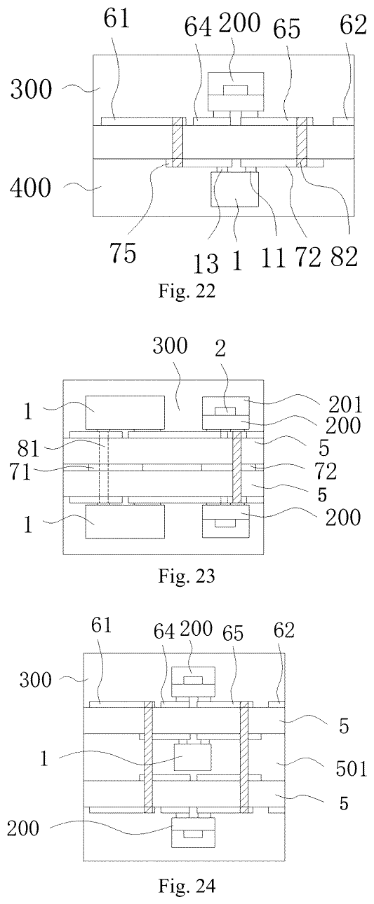

FIG. 22 shows a longitudinal profile of the display device in the present embodiment, the main difference from Embodiment 14 is that the display device in this embodiment is also covered with a second optical adhesive layer 400 on the lower surface of the entire substrate 5 to realize the sealing protection of all devices and circuits. The substrate 5 uses transparent materials, such as glass, transparent PI, etc., so that light can be transmitted in non-wired areas to achieve high resolution transparent display.

### Embodiment 16

FIG. 23 shows a longitudinal profile of the display device in the present embodiment, in this embodiment, the display device comprises two layers of substrate 5, and three layers of metal circuit, two layers of insulating media. A negative bus 71 and a positive bus 72 are arranged in the middle of the two layers of insulating media. Set the metal circuit layer where the negative bus 71 and the positive bus 72 are located as a symmetrical plane, the substrate 5, and the driver IC 1, and the MiP package 200 arranged on the substrate 5 are set symmetrically. Compared with embodiment 13, the two display pixel units in this embodiment are set back to back, thus achieving a high-resolution display on both sides.

### embodiment 17

FIG. 24 shows a longitudinal profile of the display device in the present embodiment. In this embodiment, the display device comprises two layers of substrate 5, four layers of metal circuit, an embedded layer 501, and two layers of insulating media. A driver IC 1 is located in the embedded layer 501, the two substrates 5 are arranged symmetrically on the upper surface and lower surface, the two MiP packages 200 are controlled by a same driver IC 1. Thus, while realizing the double-sided display, the two MiP packages 200 on both sides receive a same driver signal, so that the display screen on both sides of the display can be synchronized in real time.

The embodiment preferred above describes an integrated Micro-LED display device, wherein a driver IC and Micro-LEDs are bonded together to a circuit to realize an N-in-one integrated driver of the driver IC and the Micro-LEDs. In each display pixel unit, the current flowing through all Micro-LEDs in the display pixel unit passes through the driver IC in the display pixel unit, increasing the current supplied to the Micro-LEDs.

The above are the better embodiments of this application, and it is clear that persons skilled in the art may make various modifications and changes to the embodiments of this application without deviating from the spirit and scope of this application, in this way, the application is also intended to cover such modifications and changes if they fall within the claims of this application and their equivalents.

1. An integrated Micro-LED display device, wherein comprising a substrate and a plurality of display pixel units bonded on the substrate, each of the display pixel unit comprises several Micro-LEDs and a driver IC which are discrete mutually, and the first surface of the substrate is provided with a first metal circuit for connecting with the display pixel units, the second surface of the substrate is provided with a second metal circuit for connecting with the display pixel units, a part of the first metal circuit and a part of the second metal circuit are connected through several conducting vias arranged on the substrate, the first metal circuit and/or the second metal circuit comprise a positive bus and a negative bus, the driver IC and the several Micro-LEDs are all flip-chips and are electrically connected between the positive bus and the negative bus, the driver IC and at least one of the bus are respectively arranged on different surfaces of the substrate.

2. The integrated Micro-LED display device according to claim 1, wherein the first metal circuit comprises a GND lead, a VCC lead, and several first LED leads corresponding to the several Micro-LEDs, the GND lead is connected with the negative bus, and the VCC lead is connected with the positive bus.

3. The integrated Micro-LED display device according to claim 2, wherein the driver IC is arranged on the first surface of the substrate, and the positive bus and the negative bus are arranged on the second surface of the substrate.

4. The integrated Micro-LED display device according to claim 3, wherein the several Micro-LEDs are arranged on the first surface of the substrate.

5. The integrated Micro-LED display device according to claim 4, wherein the several Micro-LEDs and the driver IC are set respectively above the positive bus and the negative bus.

6. The integrated Micro-LED display device according to claim 5, wherein the several Micro-LEDs belonging to the same display pixel unit are arranged in a row, and the arrangement orientation is parallel to one edge of the driver IC belonging to this display pixel unit.

7. The integrated Micro-LED display device according to claim 2, wherein the negative bus is arranged on the first surface of the substrate, and the positive bus is arranged on the second surface of the substrate.

8. The integrated Micro-LED display device according to claim 2, wherein the driver IC and the several Micro-LEDs belonging to the same display pixel unit are respectively arranged on different surfaces of the same area of the substrate.

9. The integrated Micro-LED display device according to claim 8, wherein the driver IC and the positive bus for connecting with this driver IC are arranged on the same surface of the substrate and stacked in a direction perpendicular to the substrate.

10. The integrated Micro-LED display device according to claim 9, wherein the negative bus for connecting with the driver IC is arranged on another surface of the substrate and stacked with the driver IC in a direction perpendicular to the substrate.

11. The integrated Micro-LED display device according to claim 10, wherein the extension direction of the negative bus is perpendicular to that of the positive bus.

12. The integrated Micro-LED display device according to claim 8, wherein the driver IC and the several Micro-LEDs belonging to the same display pixel unit are stacked in a direction perpendicular to the substrate.

13. The integrated Micro-LED display device according to claim 8, wherein the Micro-LEDs are a combination of three primary colors Micro-LEDs which comprise blue Micro-LED and green Micro-LED and red Micro-LED, or a combination of a blue MicroLED, and a blue Micro-LED coated with red fluorescent material, and a blue Micro-LED coated with green fluorescent material.

14. The integrated Micro-LED display device according to claim 1, wherein a part of or all of the Micro-LEDs belonging to the same display pixel unit are fixed on a same supporting base to form a N-in-one Micro-LED and are bonded to the substrate through the same supporting base.

15. The integrated Micro-LED display device according to claim 14, wherein the N-in-one Micro-LED is provided with an island-shaped luminous structure, and the island-shaped luminous structure is a cylinder or a hollow circular cylinder.

16. The integrated Micro-LED display device according to claim 1, wherein a single display pixel unit has four Micro-LEDs.

17. The integrated Micro-LED display device according to claim 16, wherein two of the four Micro-LEDs emit red light, and the others thereof emit blue light and green light respectively.

18. The integrated Micro-LED display device according to claim 16, wherein the four Micro-LEDs emit red light, blue light, green light and white light respectively.

19. The integrated Micro-LED display device according to claim 1, wherein the several Micro-LEDs are packaged as MiP packages.

20. The integrated Micro-LED display device according to claim 1, wherein an optical adhesive layer is covered above and/or below the MiP package, the display pixel unit and/or the substrate for sealing protection.

21. The integrated Micro-LED display device according to claim 1, wherein the surface of the driver IC is covered by a light shielding layer for shading treatment.

22. The integrated Micro-LED display device according to claim 1, wherein the substrate is transparent.

23. The integrated Micro-LED display device according to claim 4, wherein the first surface on which the Micro-LEDs are arranged is setting as the front side, a number of Micro-LEDs are symmetrically arranged on the back side to achieve a double-sided display.

24. The integrated Micro-LED display device according to claim 23, wherein a same driver IC is employed to drive the Micro-LED on both sides.

25. The integrated Micro-LED display device according to claim 1, wherein the multiple display pixel units are arranged in an array, and the driver ICs for the display pixel units arranged in a same row are connected in series from end to end to form an electrical connection.

26. The integrated Micro-LED display device according to claim 2, wherein the driver IC is provided with a VCC pin, a GND pin and several LED pins corresponding to the several Micro-LEDs, the VCC pin is electrically connected with the VCC lead, the GND pin is electrically connected with the GND lead.

27. The integrated Micro-LED display device according to claim 26, wherein the several Micro-LEDs are provided with positive pins and negative pins, the several positive pins are electrically connected to the VCC lead, the several negative pins are electrically connected to the corresponding first LED leads, and the LED pins are electrically connected to the corresponding first LED leads respectively, so as to make the current flowing through the Micro-LEDs in the display pixel unit flow past the driver IC in the display pixel unit.

28. A display panel, wherein comprising an integrated Micro-LED display device according to claim 1.
